(19) United States
(12) Patent Application Publication
(10) Pub. No.: US 2024/0250068 A1
(43) Pub. Date: Jul. 25, 2024

(54) MECHANICAL STIFFENER FOR INTEGRATED CIRCUIT PACKAGE WITH VARYING HEAT DISSIPATION MODES

(71) Applicant: Marvell Asia Pte Ltd, Singapore (SG)

(72) Inventors: Richard Graf, Gray, ME (US); Alaba Bamido, Thousand Oaks, CA (US); Dwayne Richard Shirley, Valley Glen, CA (US); Wolfgang Sauter, Starksboro, VT (US)

(21) Appl. No.: 18/419,445

(22) Filed: Jan. 22, 2024

Related U.S. Application Data
(60) Provisional application No. 63/440,883, filed on Jan. 24, 2023.

(51) Int. Cl. H01L 25/065; H01L 23/00; H01L 23/367; H01L 23/552

(52) U.S. Cl. CPC H01L 25/0655; H01L 23/3675; H01L 23/552; H01L 23/562; H01L 24/29; H01L 24/32; H01L 24/13; H01L 24/16; H01L 24/33; H01L 24/73; H01L 2224/13147; H01L 2224/16225; H01L 2224/29105; H01L 2224/29109; H01L 2224/2919; H01L 2224/32225; H01L 2224/32245; H01L 2224/33181; H01L 2224/73204; H01L 2224/73253

(57) ABSTRACT

An integrated circuit device package includes a substrate, at least two integrated circuit dies mounted to the substrate, and a thermally conductive stiffener attached to the substrate to counteract warping of the substrate. The stiffener has a first portion in a thermally conductive relationship with a surface of a first integrated circuit die to provide a first heat dissipation mode for the first integrated circuit die, and has a second portion, different from the first portion, the second portion being configured to provide a second heat dissipation mode, different from the first heat dissipation mode, for a second integrated circuit die. The stiffener may be configured to expose a surface of the second integrated circuit die through an opening in the stiffener. A heat sink may be disposed in a thermally conductive relationship with the second integrated circuit die through the opening in the stiffener.

### CROSS REFERENCE TO RELATED APPLICATION

This disclosure claims the benefit of copending, commonly-assigned U.S. Provisional patent application No. 63/440,883, filed Jan. 24, 2023, which is hereby incorporated by reference herein in its entirety.

### FIELD OF USE

This disclosure relates to improved mechanical stiffeners for integrated circuit devices. More particularly, this disclosure relates to mechanical stiffeners for an integrated circuit package with varying heat dissipation modes for different components of the package.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

Typically, a mechanical stiffener may be applied to the substrate of an integrated circuit package to prevent or counteract warping of the package, which may be of particular concern when one or more integrated circuit dies are coupled to the substrate by a contact system (e.g., a ball-grid array) that may be adversely affected by warping. However, such a stiffener may adversely affect heat dissipation performance.

### SUMMARY

In accordance with implementations of the subject matter of this disclosure, an integrated circuit device package includes a substrate, at least two integrated circuit dies mounted to the substrate, and a thermally conductive stiffener attached to the substrate to counteract warping of the substrate, the stiffener having a first portion in a thermally conductive relationship with a surface of a first integrated circuit die among the at least two integrated circuit dies to provide a first heat dissipation mode for the first integrated circuit die, and having a second portion, different from the first portion, the second portion configured to provide a second heat dissipation mode, different from the first heat dissipation mode, for a second integrated circuit die among the at least two integrated circuit dies.

In a first implementation of such a package, the stiffener may be configured to overlay the first integrated circuit die among the at least two integrated circuit dies, and define an opening at least partially exposing a surface of the second integrated circuit die among the at least two integrated circuit dies die to provide the second heat dissipation mode for the second integrated circuit die among the at least two integrated circuit dies.

A first aspect of that first implementation may further include a heat sink, the heat sink being disposed in a thermally conductive relationship with the second integrated circuit die among the at least two integrated circuit dies through the opening in the stiffener, and configured to dissipate heat from the second integrated circuit die among the at least two integrated circuit dies.

In a first instance of that first aspect of that first implementation, the heat sink may be disposed in a thermally conductive relationship with the second integrated circuit die among the at least two integrated circuit dies without being in thermally conductive contact with the first integrated circuit die among the at least two integrated circuit dies.

A second implementation of such a package may further include a heat sink disposed in a thermally conductive relationship with the stiffener, the heat sink being configured to dissipate heat from the first integrated circuit die among the at least two integrated circuit dies.

A third implementation of such a package may further include a thermal interface material (TIM) disposed between the first portion of the stiffener and the surface of the first integrated circuit die among the at least two integrated circuit dies, the TIM thermally coupling the first portion of the stiffener to the first integrated circuit die among the at least two integrated circuit dies.

According to a first aspect of that third implementation, the TIM may include a thermally-conductive polymer.

According to a second aspect of that third implementation, the TIM may be a metallic TIM including at least one of indium or gallium.

In a fourth implementation of such a package, the stiffener may include at least one of stainless steel or nickel-coated copper.

A fifth implementation of such a package may further include an adhesive disposed between the thermally conductive stiffener and the substrate for attaching the stiffener to the substrate.

According to a first aspect of that fifth implementation, the adhesive may be electrically conductive, and the adhesive and the stiffener may be configured to form a shielding enclosure to shield one or more of the at least two integrated circuit dies from electromagnetic interference.

In a first instance of that first aspect of that fifth implementation, the adhesive may be electrically grounded.

In accordance with implementations of the subject matter of this disclosure, a method for packaging an integrated circuit, including a substrate and at least two integrated circuit dies mounted to the substrate, includes attaching a thermally conductive stiffener to the substrate to counteract warping of the substrate, arranging a first portion of the stiffener in a thermally conductive relationship with a surface of a first integrated circuit die among the at least two integrated circuit dies to provide a first heat dissipation mode for the first integrated circuit die among the at least two integrated circuit dies, and arranging a second portion of the stiffener, different from the first portion, to provide a second heat dissipation mode, different from the first heat dissipation mode, for a second integrated circuit die among the at least two integrated circuit dies.

A first implementation of such a method may further include configuring the stiffener to overlay the first integrated circuit die among the at least two integrated circuit dies, and at least partially exposing, through an opening in the stiffener, a surface of the second integrated circuit die among the at least two integrated circuit dies die to provide the second heat dissipation mode for the second integrated circuit die among the at least two integrated circuit dies.

A first aspect of that first implementation may further include disposing a heat sink in a thermally conductive relationship with the second integrated circuit die among the at least two integrated circuit dies through the opening in the stiffener, and configuring the heat sink to dissipate heat from the second integrated circuit die among the at least two integrated circuit dies.

A first instance of that first aspect of that first implementation may further include disposing the heat sink in a thermally conductive relationship with the second integrated circuit die among the at least two integrated circuit dies without being in thermally conductive contact with the first integrated circuit die among the at least two integrated circuit dies.

A second implementation of such a method may further include disposing a heat sink in a thermally conductive relationship with the stiffener, the heat sink being configured to dissipate heat from the first integrated circuit die among the at least two integrated circuit dies.

A third implementation of such a package may further include disposing a thermal interface material (TIM) between the first portion of the stiffener and the surface of the first integrated circuit die among the at least two integrated circuit dies, the TIM thermally coupling the first portion of the stiffener to the first integrated circuit die among the at least two integrated circuit dies.

According to a first aspect of that third implementation, disposing the TIM may include disposing a heat-dissipating polymer.

According to a second aspect of that third implementation, disposing the TIM may include disposing a metallic TIM including at least one of indium or gallium.

In a fourth implementation of such a method, attaching the stiffener may include attaching a stiffener including at least one of stainless steel or nickel-coated copper.

In a fifth implementation of such a method, attaching the thermally conductive stiffener to the substrate may include attaching the thermally conductive stiffener to the substrate with an adhesive disposed between the thermally conductive stiffener and the substrate.

According to a first aspect of that fifth implementation, the adhesive may be electrically conductive, and the method may further include configuring the adhesive and the stiffener to form a shielding enclosure to shield one or more of the at least two integrated circuit dies from electromagnetic interference.

A first instance of that first aspect of that fifth implementation may further include electrically grounding the adhesive.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 is a cross-sectional view of a portion of an integrated circuit package in accordance with implementations of the subject matter of this disclosure;

FIG. 2 a cross-sectional view of a portion of an integrated circuit package in accordance with other implementations of the subject matter of this disclosure;

FIG. 3 is a plan view of the portion of the integrated circuit package of FIG. 1, taken from line 3-3 of FIG. 1;

FIG. 4 is a cross-sectional view, similar to FIG. 1, of a portion of an integrated circuit package in accordance with further implementations of the subject matter of this disclosure;

FIG. 5 is a plan view, similar to FIG. 3, of a portion of an integrated circuit package including a mechanical stiffener in accordance with different implementations of the subject matter of this disclosure;

FIG. 6 is a cross-sectional view, similar to FIG. 2, of a portion of an integrated circuit package including a mechanical stiffener and multiple heat sinks for varying modes of heat dissipation; and

FIG. 7 is a flow diagram of a method for attaching a mechanical stiffener with varying modes of heat dissipation to integrated circuit packaging, in accordance with implementations of the subject matter of this disclosure.

### DETAILED DESCRIPTION

An integrated circuit die is typically provided in an electronic device in the form of an integrated circuit package which may include encapsulation of the integrated circuit die, as well as external contacts coupled to input/output terminals of the integrated circuit die. An integrated circuit package may include a substrate on which a die or dies are mounted. There may be different types of external contacts, but also different types of contacts between the integrated circuit dies and input/output terminals on the substrate. A common type of contact between an integrated circuit die and the substrate is a bump, such as a copper pillar bump or C4 solder bump. Such bumps can be sensitive to warping of the substrate, which might break electrical contact between individual or bumps and the substrate. It is additionally desirable to counteract warping to improve the yield of device assembly processes, as well as to preserve electrical contact of connections between the substrate and a printed circuited board to which the substrate is mounted (e.g., where such electrical contact is made by a ball-grid array or land-grid array).

To protect an integrated circuit package, including the contacts between balls or lands and the substrate, known stiffeners (e.g., metal components placed on top of a substrate without thermally contacting a heat dissipating device) are applied to counteract warping. Such stiffeners may have the positive effects of providing mechanical protection for integrated circuit dies of the package. However, known stiffeners may not provide suitable thermal management (e.g., they may trap heat that is generated by operating electronics, or they may provide insufficient heat sinking to dissipate such heat) or electromagnetic shielding (e.g., due to not covering an electronic device and/or not being electrically or mechanically coupled to an electronic device).

To protect an integrated circuit die, known heat spreaders may be applied to a top surface of one or more integrated circuit die of the package. Such heat spreaders may provide, to the one or more integrated circuit die, heat dissipation, mechanical support, and electromagnetic shielding. However, known heat spreaders may not counteract warping of the substrate. Moreover, known heat spreaders applied over two or more integrated circuit dies may thermally couple the two or more integrated circuit dies, even though it may be desirable to thermally decouple these dies.

The present disclosure provides a mechanical stiffener that counteracts warping and provides heat spreading while allowing for different thermal dissipation modes for different integrated circuit dies protected by the stiffener. In particular, the mechanical stiffener may provide various different modes of heat dissipation and electromagnetic shielding to the respective integrated circuit dies that are mounted on a substrate to which the mechanical stiffener is attached.

In an illustrative implementation, there are at least two integrated circuit dies mounted to a single substrate (e.g., silicon or other suitable materials). These dies may be mounted to the substrate using solder material (e.g., as applied using C2, C4 or other suitable methods) or other electrically conductive material (e.g., copper standoffs or other metal standoffs). Each integrated circuit die may thus connect electrically to an array of input/output terminals to facilitate coupling of the respective die to other components on the substrate, or to additional substrates that may be coupled to the single substrate, e.g., through a printed circuit board.

In accordance with implementations of the subject matter of this disclosure, a mechanical stiffener is affixed or attached to the substrate to prevent warping of the substrate (caused, e.g., by the effects of heating and mismatched coefficients of thermal expansion), thereby maintaining electrical contact between the terminals of each integrated circuit die and the corresponding terminals on the substrate. Preventing warping of the substrate may also protect the integrated circuit dies from damage that may result from stress caused by warping. In some implementations, the mechanical stiffener may be affixed or attached around the edge of the substrate, but may extend over the substrate, including over the integrated circuit dies mounted on the substrate, as described below. In such a case, the stiffener may also act as a cover to dissipate heat from the integrated circuit dies, electromagnetically shield the integrated circuit dies, and protect the integrated circuit dies from damage caused by other mechanical forces (e.g., as may arise during packaging, handling, transportation, or operational use).

In this illustrative implementation, the first and second integrated circuit dies may have different requirements for thermal heat dissipation, junction temperature, target temperature range, or any combination thereof. For example, the first die may generate a first amount of heat during its intended operation while the second die may generate a second amount of heat, different from the first amount of heat, during its intended operation. If the mechanical stiffener was thermally coupled to both the first and second integrated circuit dies, then those dies would be thermally coupled to each other and their different heat dissipation requirements could not be separately accommodated. However, in accordance with the subject matter of this disclosure, an opening may be provided in the stiffener to expose a surface of the second integrated circuit die and thereby accommodate varying thermal requirements (e.g., varying heat dissipation modes, varying junction temperatures, varying operating temperature ranges, or any combination thereof). In some implementations—e.g., when the second amount of heat is greater than the first amount of heat—an external heat sink, capable of dissipating the second amount of heat, can be disposed in a thermally conductive relationship with the second integrated circuit die through the opening. In some implementations—e.g., when the second amount of heat is less than the first amount of heat—convective heat transfer through the opening may be capable of dissipating the second amount of heat. In some implementations—e.g., when the first amount of heat is greater than that which can be dissipated by the stiffener—an external heat sink, capable of dissipating the balance of heat, can be disposed in a thermally conductive relationship with the stiffener.

Thus, a stiffener in accordance with implementations of the subject matter of this disclosure may counteract warping of the substrate and provide different heat dissipation modes for different integrated circuit dies according to a level of heat dissipation needed by respective different integrated circuit dies, based on the amount of heat generated by each respective integrated circuit die. In some implementations, any number of integrated circuit dies may be mounted on the substrate, protected by the stiffener, electrically shielded from interference and noise by the stiffener, and provided with a respective heat dissipation mode based on a configuration of the stiffener.

In some implementations, the stiffener is made from a material that provides mechanical stiffness, is thermally conductive for providing heat dissipation, may be electrically conductive for providing electrical shielding, and is attached to the substrate using an adhesive or other suitable fastening technique. In some implementations, the stiffener material may be a metal—e.g., stainless steel or nickel-coated copper. If the adhesive also is electrically conductive, the electrical shielding may be even more effective—e.g., both because the adhesive will extend the conductive enclosure formed by the stiffener, and because the adhesive may contact a circuit path for discharging electromagnetic energy picked up by the stiffener. In some implementations, the conductive adhesive may be connected to electrical ground or another suitable reference voltage—e.g., through the substrate or through electrical contact to a grounded terminal—to further improve the electrical shielding.

In some implementations, a thermal interface material (TIM) may be disposed between the stiffener and a surface of at least one integrated circuit die to provide a thermally conductive coupling between the integrated circuit die and the stiffener. The TIM may improve thermal coupling between the one or more integrated circuit dies and the stiffener. In some implementations, the TIM can be a heat-dissipating polymer TIM. In other implementations, the TIM can be a metallic TIM that may include, e.g., gallium or indium. In some implementations, the TIM can be based on any other suitable and thermally conductive material (e.g., graphite, graphene, carbon nanotubes, diamond, highly doped silicon, conductive epoxy, metal nanomaterials, any other conductive material, or any combination thereof).

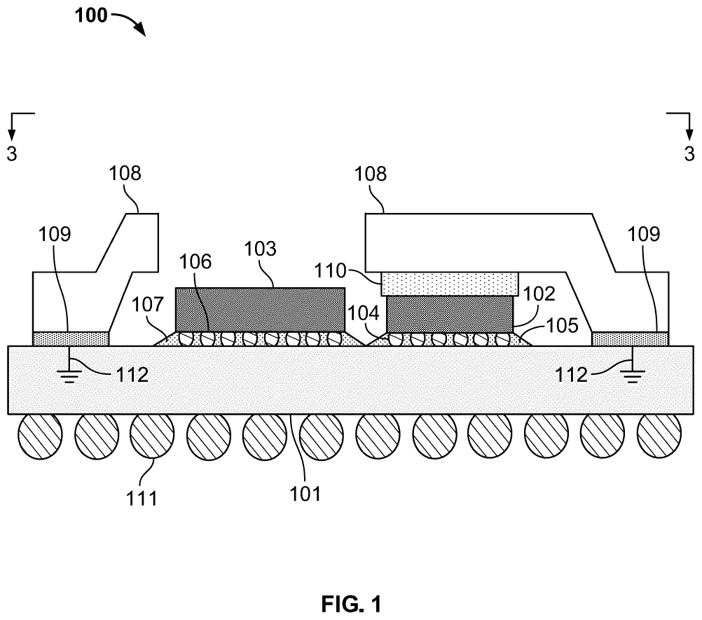

The subject matter of this disclosure may be better understood by reference to FIGS. 1-7.

FIG. 1 is a cross-sectional view of a portion of an integrated circuit package 100 including a thermally conductive mechanical stiffener and various modes of heat dissipation, in accordance with some implementations of the present disclosure. Integrated circuit package 100 includes substrate 101 (e.g., silicon or other suitable materials), to which first integrated circuit die 102 and second integrated circuit die 103 are respectively mounted. In some implementations, the first and second integrated circuit dies 102, 103 have different requirements for heat dissipation—e.g., because they generate different amounts of heat during operation or have components with different maximum operating temperature limits. In some implementations, the first and second integrated circuit dies 102, 103 are respective system on a chip (SOC) architectures and integrated circuit package 100 is a multi-chip module (MCM).

First integrated circuit die 102 is mounted to substrate 101 through electrical contacts 104 (e.g., solder, copper standoffs, or any other suitable conductive material), where electrical contacts 104 connect input/output terminals of first integrated circuit die 102 with other electronic components (e.g., substrate 101, second integrated circuit die 103, additional components mounted to substrate 101, additional components of an integrated circuit package including substrate 101, or any combination thereof). For example, electrical contacts 104 may be a copper pillar bump or a C4 solder bump. Underfill epoxy 105 further mounts first integrated circuit die 102 to substrate 101 (e.g., to provide additional mechanical or thermal support to the corresponding interface). In some implementations, underfill epoxy 105 surrounds electrical contacts 104, as shown.

Second integrated circuit die 103 is similarly mounted to substrate 101 through electrical contacts 106 (e.g., a flip chip interconnect of copper pillar bump, or C4 solder bump) and underfill epoxy 107. In some implementations, based on the respective properties of first integrated circuit die 102 and second integrated circuit die 103, these dies may have respective configurations of electrical contacts 104 and 106 and underfill epoxies 105 and 107 (e.g., to provide respective numbers of input/output channels, to provide respective requirements for mechanical or thermal support, to accommodate respective die geometries or materials, or any combination thereof).

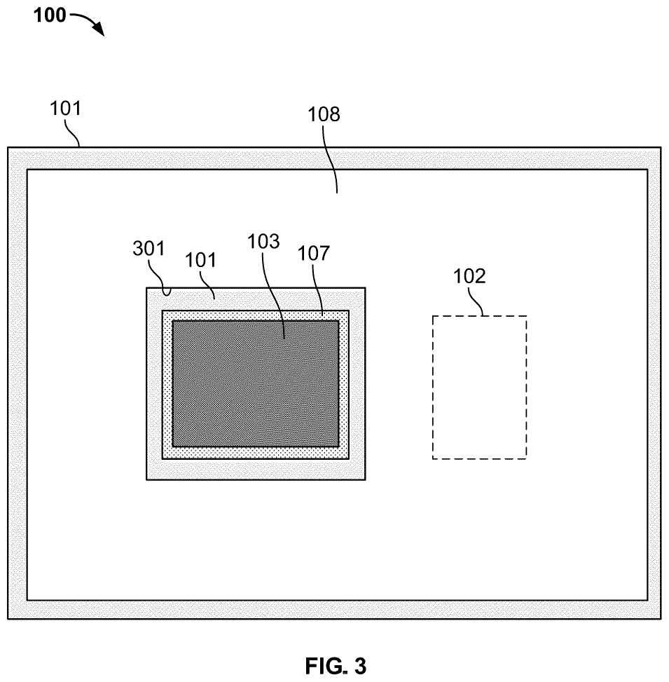

In the implementations depicted in FIG. 1, mechanical stiffener 108 is attached to the edge of substrate 101 by adhesive 109. As shown, mechanical stiffener 108 attaches to edge portions of substrate 101 and is configured to extend over at least a portion of the center of substrate 101 (e.g., as shown in FIG. 3). In some implementations, adhesive 109 is electrically conductive and may be electrically connected to ground 112 (or another suitable reference voltage), as shown (e.g., through substrate 101 or through a surface electrode over which adhesive 109 may be disposed).

In some implementations, mechanical stiffener 108 may be configured to reduce a required bond line thickness associated with thermal interface material 110, thereby improving the tolerance of the corresponding package to geometric variations of the surfaces of first and second integrated circuit dies 102, 103.

During the possible integration of substrate 101 into broader integrated circuit packages, and during the subsequent handling and operation of such an integrated circuit package, substrate 101 may encounter warping and other mechanical stress based on the elastic modulus, stiffness, coefficient of thermal expansion, and other material properties of at least substrate 101 and mechanical stiffener 108. Based on the stiffness properties of mechanical stiffener 108 and the attachment of mechanical stiffener 108 to the edge of substrate 101, mechanical stiffener 108 may counteract such warping to preserve electrical continuity between the terminals connected by electrical contacts 104, 106, 111 and to protect substrate 101 and components mounted thereon, including first and second integrated circuit dies 102, 103, from damage by warping and other mechanical stress.

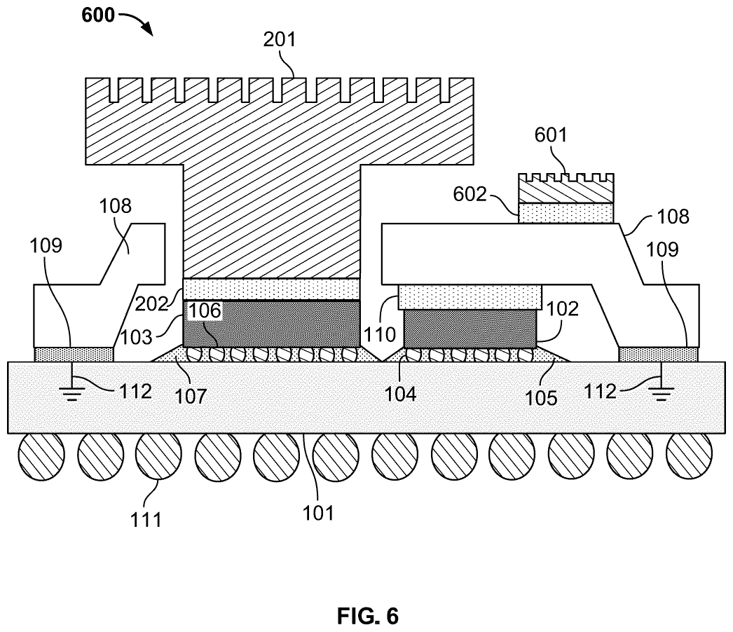

As mentioned, mechanical stiffener 108 may also be thermally conductive, in some implementations. For instance, mechanical stiffener 108 may include a metal (e.g., stainless steel or nickel-coated copper) that provides thermal conductivity. Thus, mechanical stiffener 108 may be arranged in a thermally conductive relationship with first integrated circuit die 102. In particular, thermal interface material (TIM) 110 may connect a top surface (e.g., the surface that is parallel to and furthest away from the surface of substrate 101 to which the first integrated circuit die 102 is mounted) of first integrated circuit die 102 to the underside (e.g., the surface of mechanical stiffener 108 that is closed to the top surface of first integrated circuit die 102) of mechanical stiffener 108. In some implementations, TIM 110 includes a heat-dissipating polymer or a metal alloy including at least one of indium or gallium. Through TIM 110, first integrated circuit die 102 may be in a thermally conductive relationship with mechanical stiffener 108, such that heat generated during the operation of first integrated circuit die 102 may be dissipated through mechanical stiffener 108. In particular, heat may conduct from first integrated circuit die 102, through TIM 110, to mechanical stiffener 108, and this heat may then convect or radiate from mechanical stiffener 108. In some implementations, to increase the heat dissipation capacity of mechanical stiffener 108, a heat sink (e.g., heat sink 601, as shown in FIG. 6) may be attached to the outer surface of mechanical stiffener 108. The properties of heat sink 601 (e.g., size, number of fins, or other thermal property) may be based on a heat dissipation requirement of first integrated circuit die 102. In some implementations, a TIM (e.g., TIM 602, as shown in FIG. 6, which may include any of the aforementioned TIM materials) may be disposed between a surface of a heat sink (e.g., heat sink 601) and a corresponding surface of a mechanical stiffener (e.g., mechanical stiffener 108) to improve the thermal coupling between the heat sink and the mechanical stiffener.

As mentioned, mechanical stiffener 108 may also be electrically conductive (e.g., it may be made of stainless steel or nickel-coated copper), in some implementations. Based on the electrical conductivity of mechanical stiffener 108 and its geometric arrangement around first and second integrated circuit dies 102, 103, mechanical stiffener 108 may shield first and second integrated circuit dies 102, 103 from electromagnetic interference or electronic noise. In particular, mechanical stiffener 108 may shunt such interference or noise to ground 112 (e.g., through a ground connection to electrically conductive adhesive 109, as shown). In some implementations, based on the configuration of mechanical stiffener 108, varying modes of electrical shielding are respectively provided to first and second integrated circuit dies 102, 103.

Thus, mechanical stiffener 108, in accordance with implementations of the present disclosure, may provide mechanical stiffening to substrate 101 while further providing heat dissipation, mechanical support, and electromagnetic shielding to one or more integrated circuit die (e.g., one or more of first and second integrated circuit dies 102, 103).

As mentioned above, first and second integrated circuit dies 102, 103 may have respectively different requirements for thermal dissipation. For instance, second integrated circuit die 103 may generate a different amount of heat during operation, or may have a different maximum temperature limit than first integrated circuit die 102. Therefore, mechanical stiffener 108 may be arranged to provide respectively different heat dissipation modes to first and second integrated circuit dies 102, 103. In particular, mechanical stiffener 108 may be configured to at least partially expose the top surface (i.e., the surface that is parallel to and furthest away from the surface of substrate 101 to which the second integrated circuit die 103 is mounted) of second integrated circuit die 103. For example, mechanical stiffener 108 may have an opening (e.g., opening 301 as shown in FIG. 3) exposing the top surface of second integrated circuit die 103, such that at least a portion of second integrated circuit die 103 is exposed to the ambient environment, thereby providing a second heat dissipation mode for second integrated circuit die 103, different from the first heat dissipation mode provided for first integrated circuit die 102.

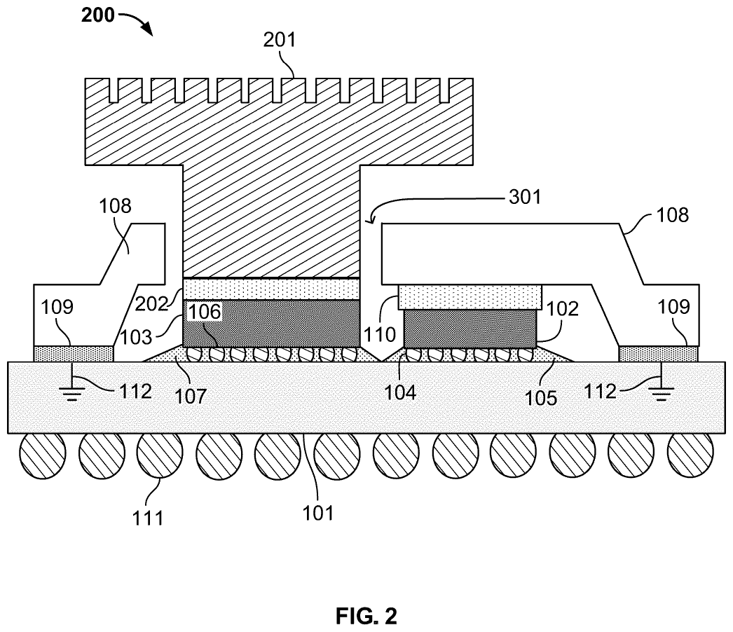

In some implementations, a heat sink (e.g., heat sink 201, as shown in FIG. 2) may be attached to and in a thermally conductive relationship with the top surface of second integrated circuit die 103 through the opening (e.g., opening 301) in mechanical stiffener 108. In some implementations, a TIM (e.g., TIM 202, as shown in FIG. 2, which may include any of the aforementioned TIM materials) may be disposed between a surface of a heat sink (e.g., heat sink 201) and a corresponding surface of an integrated circuit die (e.g., second integrated circuit die 103) to improve the thermal coupling between the heat sink and the integrated circuit die. Heat sink 201 may be configured to dissipate heat from the second integrated circuit die 103—e.g., by conduction of heat from the second integrated circuit die 103 into heat sink 201 and then convection or radiation of that heat from heat sink 201 to the ambient environment. The properties of heat sink 201 (e.g., size, number of fins, or other thermal property) may be based on at least a heat dissipation requirement of second integrated circuit die 103. In some implementations, the thermal properties of heat sink 201 may be exclusively based on the heat dissipation requirements of second integrated circuit die 103. In other implementations, the thermal properties of heat sink 201 may be additionally based on the heat dissipation requirements of other dies.

In some implementations, the opening in mechanical stiffener 108 may be configured, without a heat sink, to convectively or radiatively dissipate heat from the second integrated circuit die 103.

Substrate 101 may further connect electrically to other components based on electrical contacts 111 (e.g., a copper pillar bump, C4 solder bump, or other suitable electrical connection), which are included on the underside (e.g., the surface that is opposite the surface to which the integrated circuit dies are mounted) of substrate 101. Based on the provisions of mechanical stiffener 108 to counteract the effects of substrate 101 warping, electrical continuity may be preserved between substrate 101 and components electrically connected to substrate 101 through electrical contacts 111.

It is noted that FIGS. 1-6 may not be drawn to scale. It is also noted that these depictions are for the purposes of illustration, and that other implementations may be realized without departing from the teachings of the current disclosure. For example, substrate 101 may include additional integrated circuit dies, each of which may be thermally coupled to mechanical stiffener 108, at least partially exposed by an opening in mechanical stiffener 108, or a combination thereof. Moreover, substrate 101 may include additional electronic components (e.g., passive or active electronic devices), as described below. Additionally, any other suitable number of heat sinks may be respectively attached to surfaces of the integrated circuit dies or surfaces of the stiffener.

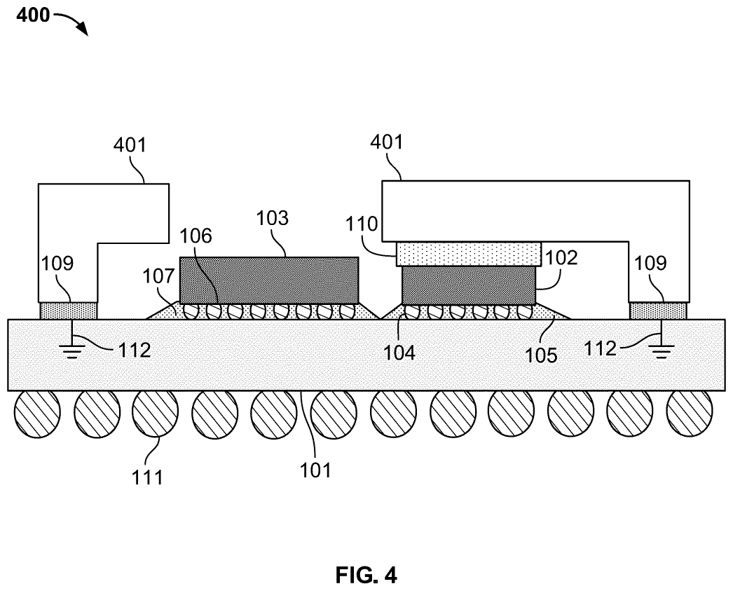

FIG. 4 is a cross-sectional view of a portion of integrated circuit package 400, similar to integrated circuit package 100 but having a flat mechanical stiffener 401 in place of the coined mechanical stiffener 108. Flat mechanical stiffener 401 has vertical (i.e., having an effectively ninety-degree angle) sidewalls, in contrast to the oblique sidewalls of coined mechanical stiffener 108, as shown in FIG. 1. Mechanical stiffener 401 may otherwise retain the structural and performative aspects of mechanical stiffener 108. In some implementations, the top surface (e.g., the surface opposite to the surface bonded to substrate 101) of mechanical stiffener 401 is flat and at an effectively uniform height across the entire footprint of the stiffener—e.g., to realize flush coupling to a flat lid attached thereon.

In some implementations, either of mechanical stiffener 108 or mechanical stiffener 401 may be fabricated by any of a stamping, forging, or machining (e.g., electro-discharge machining) process.

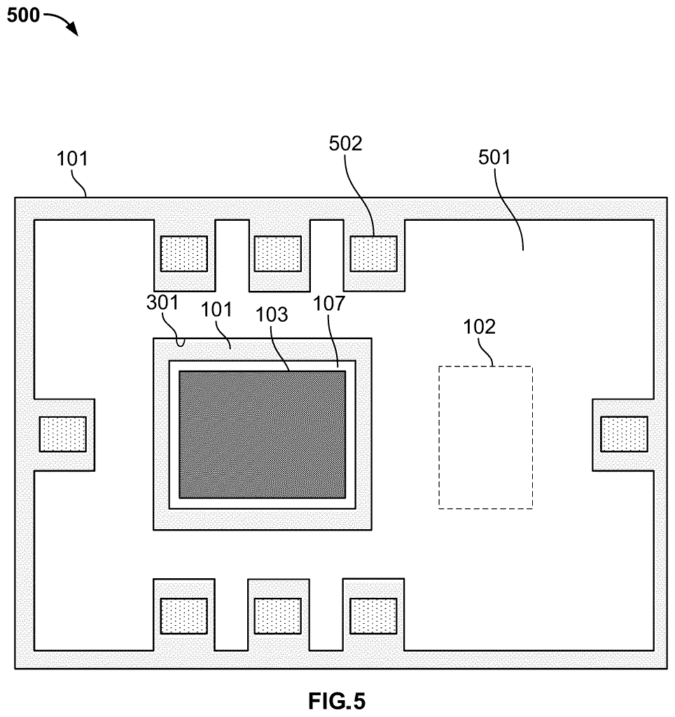

FIG. 5 is a plan view of a portion of integrated circuit package 500, similar to integrated circuit packages 100 or 400 but having additional openings to accommodate other structures. As shown in FIG. 5, mechanical stiffener 501 includes multiple openings around its perimeter, each of which corresponds to a position of an electronic device (e.g., electronic device 502, which may be a capacitor or any other passive or active circuit component). In some implementations, electronic devices may be positioned in openings of mechanical stiffener 501 because they are too bulky to fit under mechanical stiffener 501, they are attached to substrate 101 after the attachment of mechanical stiffener 501, or it is desirable to decouple heat dissipated by these devices from mechanical stiffener 501 (and other devices to which mechanical stiffener 501 is thermally coupled). For example, electronic device 502 may be a bypass capacitor to shunt electronic noise (e.g., from a power supply) to ground and prevent such noise from affecting first and second integrated circuit dies 102, 103. Because each electronic device 502 may serve more than one integrated circuit die, or may occupy a large physical area, it may be desirable to place these devices directly on substrate 101 (e.g., through the openings in mechanical stiffener 501) rather than to integrate these devices with one or more integrated circuit dies.

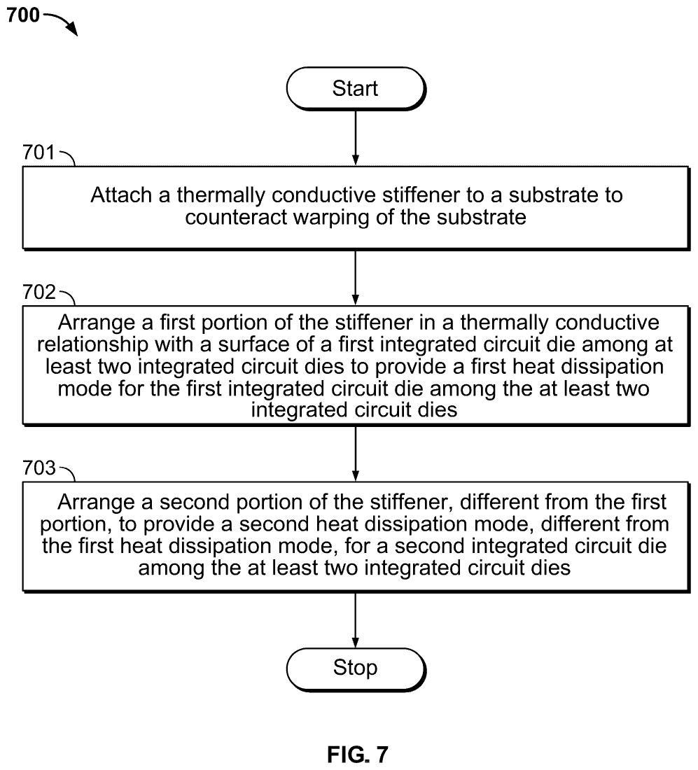

FIG. 7 is a flow diagram of a method 700 for providing a mechanical stiffener to integrated circuit packaging with varying modes of heat dissipation, in accordance with implementations of the subject matter of this disclosure. At 701, method 700 begins with attaching a thermally conductive stiffener (e.g., mechanical stiffener 108, 401, or 501) to a substrate (e.g., substrate 101) to counteract warping of the substrate.

At 702, a first portion (e.g., the portions of mechanical stiffeners 108, 501 overlaying the dotted outline of first integrated circuit die 102, as respectively shown in FIGS. 3 and 5) of the stiffener is arranged in a thermally conductive relationship with a surface of a first integrated circuit die (e.g., first integrated circuit die 102) among at least two integrated circuit dies (e.g., first and second integrated circuit dies 102, 103) mounted to the substrate to provide a first heat dissipation mode for the first integrated circuit die. For example, the first heat dissipation mode may include dissipating, using the mechanical stiffener, the heat generated by operation of the first integrated circuit die. In some implementations, a TIM (e.g., TIM 110) may be included between the first portion of the stiffener and the surface of the first integrated circuit die to improve the conductive properties of the thermally conductive relationship. In some implementations, the method may also include attaching a heat sink (e.g., heat sink 601) to the mechanical stiffener to increase a heat dissipation capacity of the mechanical stiffener, and the first heat dissipation mode may thus include dissipating heat from the mechanical stiffener through the heat sink.

At 703, method 700 concludes with arranging a second portion (e.g., the portions of mechanical stiffeners 108, 501 outlining the opening 301, as respectively shown in FIGS. 3 and 5) of the stiffener, different from the first portion, to provide a second heat dissipation mode, different from the first heat dissipation mode, for a second integrated circuit die (e.g., integrated circuit die 103) among the at least two integrated circuit dies. In some implementations, the second heat dissipation mode is based on an opening in the stiffener, whereby the second portion of the stiffener surrounds an edge of the second integrated die to expose a surface of the second integrated die. In some implementations, the method also includes attaching a heat sink (e.g., heat sink 201) to the second integrated die (e.g., through the opening surrounded by the second portion of the stiffener) to improve a heat dissipation capacity of the second heat dissipation mode. By virtue of the different first and second heat dissipation modes, the method 700 decouples the thermal dissipation properties of the first and second integrated circuit dies.

In some implementations, the method 700 may be extended to substrates with three or more integrated circuit dies. For example, each integrated circuit die may have a respective heat dissipation mode based on portions of the stiffener that thermally couple to or at least partially expose the top surfaces of each integrated circuit die.

In some implementations, aspects of the present disclosure may be incorporated into multi-chip module (MCM) packaging including integration of multiple integrated circuit dies or chiplets, where each respective die or chiplet may include a discrete system on chip (SOC).

Thus it is seen that an apparatus including a thermally conductive mechanical stiffener for providing mechanical support and protection, as well as various heat dissipation modes, to integrated circuit dies, has been provided.

It is noted that the foregoing is only illustrative of the principles of the invention, and that the invention can be practiced by other than the described implementations, which are presented for purposes of illustration and not of limitation, and the present invention is limited only by the claims which follow.

What is claimed is:

1. An integrated circuit device package comprising:
a substrate;
at least two integrated circuit dies mounted to the substrate; and
a thermally conductive stiffener attached to the substrate to counteract warping of the substrate, the stiffener:
having a first portion in a thermally conductive relationship with a surface of a first integrated circuit die among the at least two integrated circuit dies to provide a first heat dissipation mode for the first integrated circuit die, and
having a second portion, different from the first portion, the second portion configured to provide a second heat dissipation mode, different from the first heat dissipation mode, for a second integrated circuit die among the at least two integrated circuit dies.

2. The device package of claim 1, wherein the stiffener is configured to:
overlay the first integrated circuit die among the at least two integrated circuit dies; and
define an opening at least partially exposing a surface of the second integrated circuit die among the at least two integrated circuit dies to provide the second heat dissipation mode for the second integrated circuit die among the at least two integrated circuit dies.

3. The device package of claim 2, further comprising a heat sink, the heat sink being:
disposed in a thermally conductive relationship with the second integrated circuit die among the at least two integrated circuit dies through the opening in the stiffener; and
configured to dissipate heat from the second integrated circuit die among the at least two integrated circuit dies.

4. The device package of claim 3, wherein the heat sink is disposed in a thermally conductive relationship with the second integrated circuit die among the at least two integrated circuit dies without being in thermally conductive contact with the first integrated circuit die among the at least two integrated circuit dies.

5. The device package of claim 1, further comprising a heat sink disposed in a thermally conductive relationship with the stiffener, the heat sink being configured to dissipate heat from the first integrated circuit die among the at least two integrated circuit dies.

6. The device package of claim 1, further comprising a thermal interface material (TIM) disposed between the first portion of the stiffener and the surface of the first integrated circuit die among the at least two integrated circuit dies, the TIM thermally coupling the first portion of the stiffener to the first integrated circuit die among the at least two integrated circuit dies.

7. The device package of claim 6, wherein the TIM comprises a thermally-conductive polymer.

8. The device package of claim 6, wherein the TIM is a metallic TIM comprising at least one of indium or gallium.

9. The device package of claim 1, wherein the stiffener comprises at least one of stainless steel or nickel-coated copper.

10. The device package of claim 1, further comprising an adhesive disposed between the thermally conductive stiffener and the substrate for attaching the stiffener to the substrate.

11. The device package of claim 10, wherein the adhesive is electrically conductive, the adhesive and the stiffener being configured to form a shielding enclosure to shield one or more of the at least two integrated circuit dies from electromagnetic interference.

12. The device package of claim 11, wherein the adhesive is electrically grounded.

13. A method for packaging an integrated circuit comprising a substrate and at least two integrated circuit dies mounted to the substrate, the method comprising:
attaching a thermally conductive stiffener to the substrate to counteract warping of the substrate;
arranging a first portion of the stiffener in a thermally conductive relationship with a surface of a first integrated circuit die among the at least two integrated circuit dies to provide a first heat dissipation mode for the first integrated circuit die among the at least two integrated circuit dies; and
arranging a second portion of the stiffener, different from the first portion, to provide a second heat dissipation mode, different from the first heat dissipation mode, for a second integrated circuit die among the at least two integrated circuit dies.

14. The method according to claim 13 for packaging an integrated circuit, further comprising:
configuring the stiffener to overlay the first integrated circuit die among the at least two integrated circuit dies; and
at least partially exposing, through an opening in the stiffener, a surface of the second integrated circuit die among the at least two integrated circuit dies to provide the second heat dissipation mode for the second integrated circuit die among the at least two integrated circuit dies.

15. The method according to claim 14 for packaging an integrated circuit, further comprising:
disposing a heat sink in a thermally conductive relationship with the second integrated circuit die among the at least two integrated circuit dies through the opening in the stiffener; and
configuring the heat sink to dissipate heat from the second integrated circuit die among the at least two integrated circuit dies.

16. The method according to claim 15 for packaging an integrated circuit, further comprising disposing the heat sink in a thermally conductive relationship with the second integrated circuit die among the at least two integrated circuit dies without being in thermally conductive contact with the first integrated circuit die among the at least two integrated circuit dies.

17. The method according to claim 13 for packaging an integrated circuit, further comprising disposing a heat sink in a thermally conductive relationship with the stiffener, the heat sink being configured to dissipate heat from the first integrated circuit die among the at least two integrated circuit dies.

18. The method according to claim 13 for packaging an integrated circuit, further comprising disposing a thermal interface material (TIM) between the first portion of the stiffener and the surface of the first integrated circuit die among the at least two integrated circuit dies, the TIM thermally coupling the first portion of the stiffener to the first integrated circuit die among the at least two integrated circuit dies.

19. The method according to claim 18 for packaging an integrated circuit, wherein disposing the TIM comprises disposing a heat-dissipating polymer.

20. The method according to claim 18 for packaging an integrated circuit, wherein disposing the TIM comprises disposing a metallic TIM comprising at least one of indium or gallium.

21. The method according to claim 13 for packaging an integrated circuit, wherein attaching the stiffener comprises attaching a stiffener comprising at least one of stainless steel or nickel-coated copper.

22. The method according to claim 13 for packaging an integrated circuit, wherein attaching the thermally conductive stiffener to the substrate comprises attaching the thermally conductive stiffener to the substrate with an adhesive disposed between the thermally conductive stiffener and the substrate.

23. The method according to claim 22 for packaging an integrated circuit, wherein the adhesive is electrically conductive, the method further comprising configuring the adhesive and the stiffener to form a shielding enclosure to shield one or more of the at least two integrated circuit dies from electromagnetic interference.

24. The method according to claim 23 for packaging an integrated circuit, further comprising electrically grounding the adhesive.
